(19) United States
(12) Patent Application Publication
(10) Pub. No.: US 2007/0155187 A1
(43) Pub. Date: Jul. 5, 2007

(54) Method for preparing a gate oxide layer

(75) Inventors: Chung Yi Chen, Jhonghe City (TW); Chih Hsun Chu, Hsinchu City (TW); Jih Wen Chou, Hsinchu City (TW)

Correspondence Address: OLIFF & BERRIDGE, PLC, P.O. BOX 19928, ALEXANDRIA, VA, 22320, US

(73) Assignee: PROMOS TECHNOLOGIES INC., Hsinchu, (TW)

(21) Appl. No.: 11/387,888

(22) Filed: Mar. 24, 2006

(30) Foreign Application Priority Data
Jan. 4, 2006 (TW) 095100262

(51) Int. Cl. H01L 21/31; H01L 21/469

(52) U.S. Cl. 438/778

(57) ABSTRACT

A method for preparing a gate oxide layer is described. First, a trench surrounding an active area is formed in a substrate, and a dielectric block is then formed in the trench such that an upper surface of the dielectric block is not aligned with that of the substrate. Subsequently, an ion implantation process is performed to implant nitrogen-containing dopants into the substrate in the active area, and a thermal oxidation process is then performed to form a gate oxide layer on the surface of the substrate in the active area. Particularly, the concentration of the nitrogen-containing dopants at the center of the active area is higher than that at the edge of the active area. The nitrogen-containing dopants inhibit the reaction rate of the thermal oxidation process, so as to prevent the gate oxide layer from thinning at the edge near the trench.

### BACKGROUND OF THE INVENTION

(A) Field of the Invention

The present invention relates to a method for preparing a gate oxide layer, and more particularly, to a method for preparing a gate oxide layer, which can prevent the gate oxide layer from having a smaller thickness at the edge than at the center of the active area.

(B) Description of the Related Art

Conventional integrated circuit fabrication uses a local oxidation of silicon (LOCOS) technique or shallow trench isolation (STI) technique to electrically isolate wafer-mounted electronic devices from each other, so as to avoid short circuits and cross interference. Since the LOCOS technique forms a field oxide layer covering a larger wafer area and forms a bird's beak as well, advanced integrated circuit fabrication generally selects the STI technique to electrically isolate electronic devices.

FIG. 1 illustrates a shallow trench isolation 10 in a silicon substrate 12 according to the prior art. The shallow trench isolation 10 surrounds an active area 20, and a gate oxide layer 14 is formed on the surface of the silicon substrate 12 in the active area 20. As the size of the semiconductor device shrinks, the width of the active area 20 decreases correspondingly, which results in increasing stress at the edge of the active area 20. However, the increasing stress lowers the reaction rate of the thermal oxidation process, which forms the gate oxide layer 14. Consequently, the gate oxide layer 14 has a smaller thickness at the edge than at the center of the active area 20, and current leakage tends to occur at the edge of the active area 20.

### SUMMARY OF THE INVENTION

The primary objective of the present invention is to provide a method for preparing a gate oxide layer, which uses a self-aligned implanting process to implant nitrogen-containing dopants into the silicon substrate in the active area. The nitrogen-containing dopants inhibit the reaction rate of the thermal oxidation process, so as to prevent the gate oxide layer from having a smaller thickness at the edge than at the center of the active area.

In order to achieve the above-mentioned objective and avoid the problems of the prior art, the present invention discloses a method for preparing a gate oxide layer by implanting nitrogen-containing dopants to inhibit the reaction rate of the thermal oxidation process. According to one embodiment of the present invention, a mask layer having at least two openings is formed on a substrate, and two trenches are formed in the substrate below the two openings, wherein two trenches define an active area. A dielectric block is then formed in each of the two trenches, and the dielectric block has an upper surface not aligned with that of the substrate. Subsequently, an implanting process is performed to implant nitrogen-containing dopants into the substrate in the active area and a thermal oxidation process is then performed to form a gate oxide layer on the upper surface of the substrate in the active area.

Since the upper surface of the dielectric block is not aligned with the upper surface of the substrate, the concentration of the implanted nitrogen-containing dopants at the center is higher than that at the edge of the active area. Because the nitrogen-containing dopants inhibit the reaction rate of the thermal oxidation process, the reaction rate of the thermal oxidation process at the center is lower than that at the edge of the active area. Consequently, the present method can prevent the gate oxide layer from having a smaller thickness at the edge than at the center of the active area.

According to another embodiment of the present invention, a mask layer having at least two openings is formed on a substrate, and two trenches are formed in the substrate below the two openings; wherein two trenches define an active area. A liner oxide layer is formed on an inner wall of each of the two trenches, and the liner oxide layer has a round profile at an edge of the active area, i.e., the substrate has a taper profile between the active area and each of the two trenches. Subsequently, a dielectric block is formed in each of the two trenches, an implanting process is then performed to implant nitrogen-containing dopants into the substrate in the active area, and a thermal oxidation process is performed to form the gate oxide layer on the upper surface of the substrate in the active area.

Since the substrate has a taper profile between the active area and each of the two trenches, the concentration of the implanted nitrogen-containing dopants at the center is higher than that at the edge of the active area. Consequently, the present method can prevent the gate oxide layer from having a smaller thickness at the edge than at the center of the active area due to the inhibiting effects of the nitrogen-containing dopants on the reaction rate of the thermal oxidation process.

From the above description, the implanting process implants the nitrogen-containing dopants into the substrate in a self-aligned manner due to the difference in height between the trench and the active area or the special profile of the substrate in the active area. Furthermore, the concentration of the nitrogen-containing dopants at the edge of the active area is lower than that at the center of the active area; therefore, the present invention need not use a lithographic process to define the implanting region. In addition, the present invention can prevent the gate oxide layer from having a smaller thickness at the edge than at the center of the active area due to the inhibiting effects of the nitrogen-containing dopants on the reaction rate of the thermal oxidation process.

### BRIEF DESCRIPTION OF THE DRAWINGS

The objectives and advantages of the present invention will become apparent upon reading the following description and upon reference to the accompanying drawings in which:

FIG. 1 illustrates a shallow trench isolation according to a prior art;

FIG. 2 to FIG. 6 illustrate a method for preparing a gate oxide layer according to a first embodiment of the present invention;

FIG. 7 to FIG. 10 illustrate a method for preparing a gate oxide layer according to a second embodiment of the present invention; and

FIG. 11 to FIG. 14 illustrate a method for preparing a gate oxide layer according to a third embodiment of the present invention.

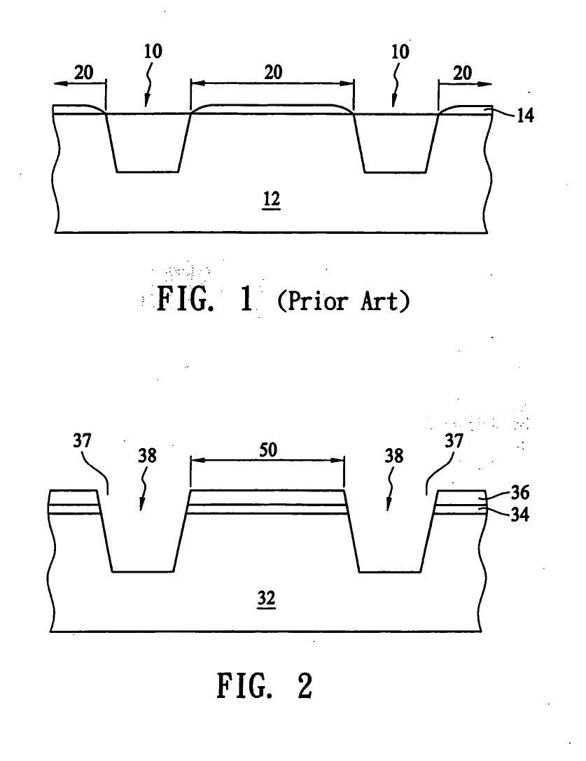

### DETAILED DESCRIPTION OF THE INVENTION

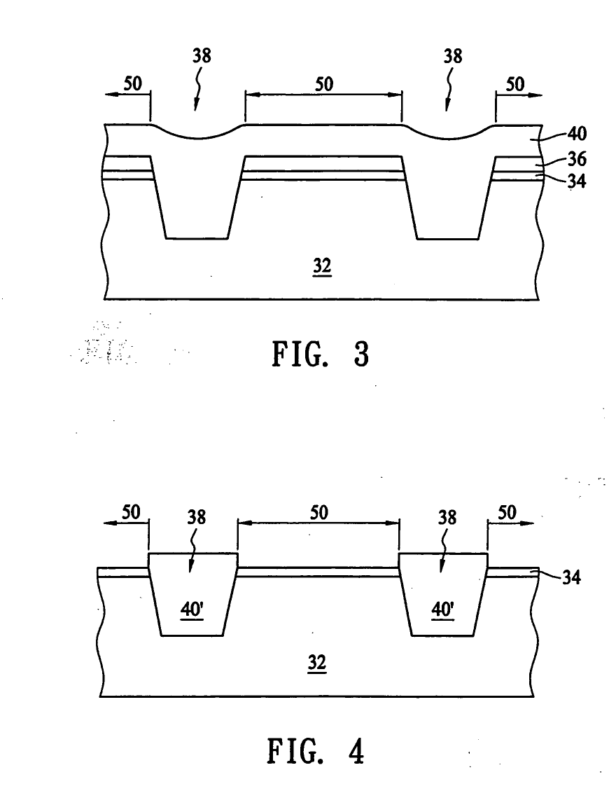

FIG. 2 to FIG. 6 illustrate a method for preparing a gate oxide layer 44 according to a first embodiment of the present invention. A pad oxide layer 34 and a mask layer 36 made of silicon nitride are formed on a silicon substrate 32 in sequence; wherein the mask layer 36 has two openings 37. An anisotropic etching process is performed to form a trench 38 in the silicon substrate 32 below each of the two openings 37, and the two adjacent trenches 38 define an active area 50. Subsequently, a chemical vapor deposition process is performed to form a uniform dielectric layer 40 made of silicon oxide, which fills the trenches 38, as shown in FIG. 3.

Referring to FIG. 4, a planarization process, such as a chemical mechanical polishing (CMP) process, is performed to remove a portion of the dielectric layer 40 above the mask layer 36 to form a dielectric block 40′ in the trench 38. Subsequently, a hot phosphoric acid solution is used as an etchant to perform a wet etching process to completely remove the mask layer 36, but to keep the pad oxide layer 34 on the silicon substrate 32 and the dielectric block 40′ in the trench 38. As a result, the dielectric block 40′ has an upper surface higher than the upper surface of the pad oxide layer 34, i.e., the upper surface of the dielectric block 40′ is higher than that of the silicon substrate 32.

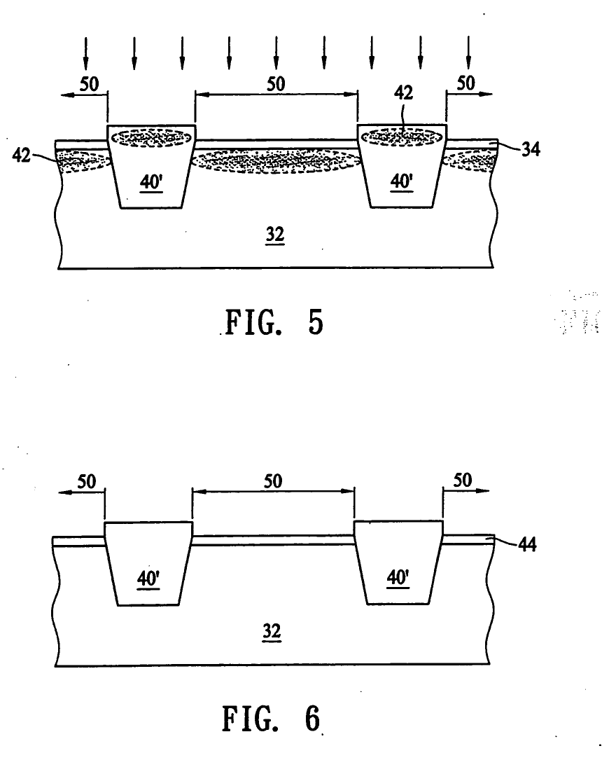

Referring to FIG. 5, an implanting process is performed to implant nitrogen-containing dopants 42 into the dielectric block 40′ and into the silicon substrate 32 in the active area 50. Preferably, the nitrogen-containing dopants 42 are ions selected from a group consisting of nitrogen atom, nitrogen gas, nitrous oxide and nitric oxide, and the implanting energy of the nitrogen-containing dopants 42 is between 10 and 30 eV. The nitrogen-containing dopants 42 are implanted into the silicon substrate 32 in the active area 50 in a Gaussian distribution manner. Furthermore, the upper surface of the dielectric block 40′ is higher than that of the silicon substrate 32; hence, the nitrogen-containing dopants 42 in the silicon substrate 32 can not diffuse to the dielectric block 40′ at different heights, and vice versa. Consequently, the distribution of the nitrogen-containing dopants 42 in the silicon substrate 32 is not uniform; in particular, the concentration of the implanted nitrogen-containing dopants 42 at the center is higher than that at the edge of the active area 50.

Referring to FIG. 6, a fluoric acid solution is used as an etchant to perform another wet etching process to completely remove the pad oxide layer 34, so as to expose the upper surface of the silicon substrate 32 in the active area 50, and a thermal oxidation process is then performed to form the gate oxide layer 44 on the upper surface of the silicon substrate 32 in the active area 50. Since the nitrogen-containing dopants 42 can inhibit the reaction rate of the thermal oxidation process and the concentration of the implanted nitrogen-containing dopants 42 at the center is higher than that at the edge of the active area 50, the oxidation rate of the thermal oxidation process at the center of the active area 50 is lower than that at the edge of the active area 50. Particularly, the inhibiting effects of the nitrogen-containing dopants 42 can compensate for the inconsistent oxidation rate between the edge and the center of the active area 50 due to stress, so as to prevent the gate oxide layer 44 from having a smaller thickness at the edge than at the center of the active area 50.

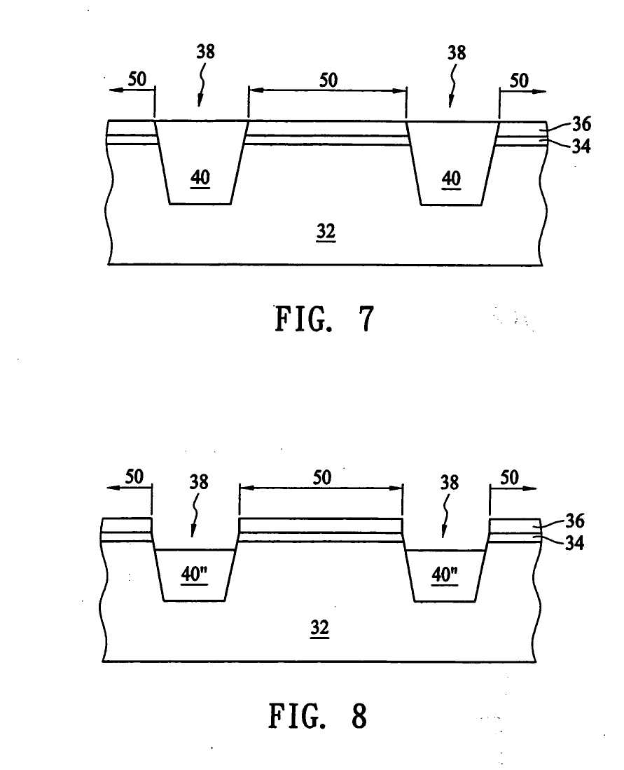

FIG. 7 to FIG. 10 illustrate a method for preparing a gate oxide layer 44′ according to a second embodiment of the present invention. The fabrication processes shown in FIG. 2 and FIG. 3 are first performed to form the trench 38 in the silicon substrate 32 and the dielectric layer 40 on the silicon substrate 32. Subsequently, a planarization process, such as a chemical mechanical polishing (CMP) process, is performed to remove a portion of the dielectric layer 40 above the mask layer 36 so that the upper surface of the dielectric layer 40 is horizontally aligned with the upper surface of the mask layer 36, as shown in FIG. 7.

Referring to FIG. 8, the mask layer 36 is used as an etching mask to perform an etching process, which forms a dielectric block 40″ by removing the dielectric layer 40 not covered by the mask layer 36 until the dielectric layer 40 is inside the silicon substrate 32; i.e., until the upper surface of the dielectric layer 40 is lower than that of the silicon substrate 32 so that the upper surface of the dielectric block 40″ is lower than that of the silicon substrate 32. In particular, the mask layer 36 made of silicon nitride can be used as an etching mask to perform an etching back process directly after the dielectric layer 40 made of silicon oxide is formed, without performing the above-mentioned planarization process.

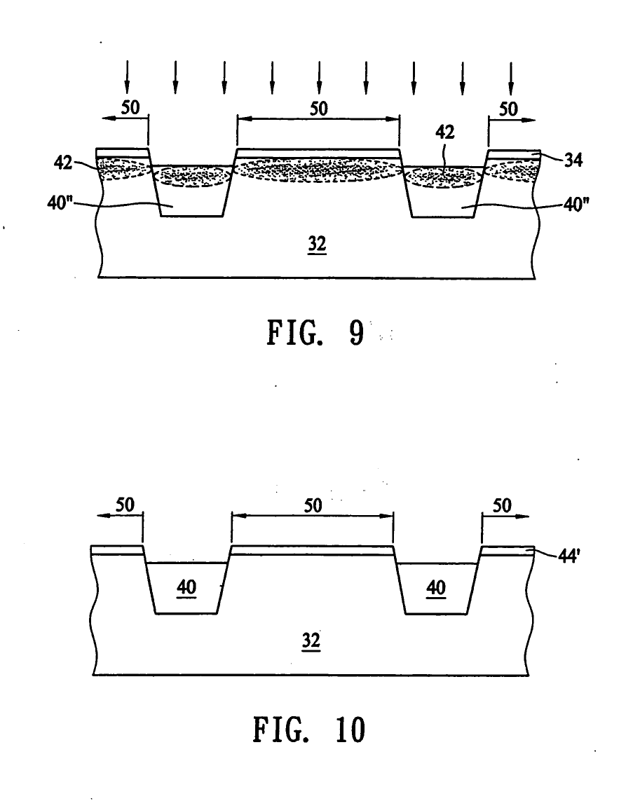

Referring to FIG. 9, a hot phosphoric acid solution is used as an etchant to perform a wet etching process to completely remove the mask layer 36, but to keep the pad oxide layer 34 on the silicon substrate 32 and the dielectric block 40″ in the trench 38. An implanting process is then performed to implant nitrogen-containing dopants 42 into the dielectric block 40″ and the silicon substrate 32 in the active area 50. The nitrogen-containing dopants 42 are implanted into the silicon substrate 32 in the active area 50 in a Gaussian distribution manner. The upper surface of the dielectric block 40″ is lower than that of the silicon substrate 32; hence, the nitrogen-containing dopants 42 in the silicon substrate 32 can not diffuse into the dielectric block 40″ at a different height, and vice versa. Consequently, the distribution of the nitrogen-containing dopants 42 in the silicon substrate 32 is not uniform; in particular, the concentration of the implanted nitrogen-containing dopants 42 at the center is higher than that at the edge of the active area 50.

Referring to FIG. 10, a fluoric acid solution is used as an etchant to perform another wet etching process to completely remove the pad oxide layer 34, so as to expose the upper surface of the silicon substrate 32 in the active area 50, and a thermal oxidation process is then performed to form the gate oxide layer 44′ on the upper surface of the silicon substrate 32 in the active area 50. Since the nitrogen-containing dopants 42 can inhibit the reaction rate of the thermal oxidation process and the concentration of the implanted nitrogen-containing dopants 42 at the center is higher than that at the edge of the active area 50, the oxidation rate at the center of the active area 50 is lower than that at the edge of the active area 50. Particularly, the inhibiting effects of the nitrogen-containing dopants 42 can compensate for the inconsistent oxidation rate between the edge and the center of the active area 50 due to stress, so as to prevent the gate oxide layer 44′ from having a smaller thickness at the edge than at the center of the active area 50.

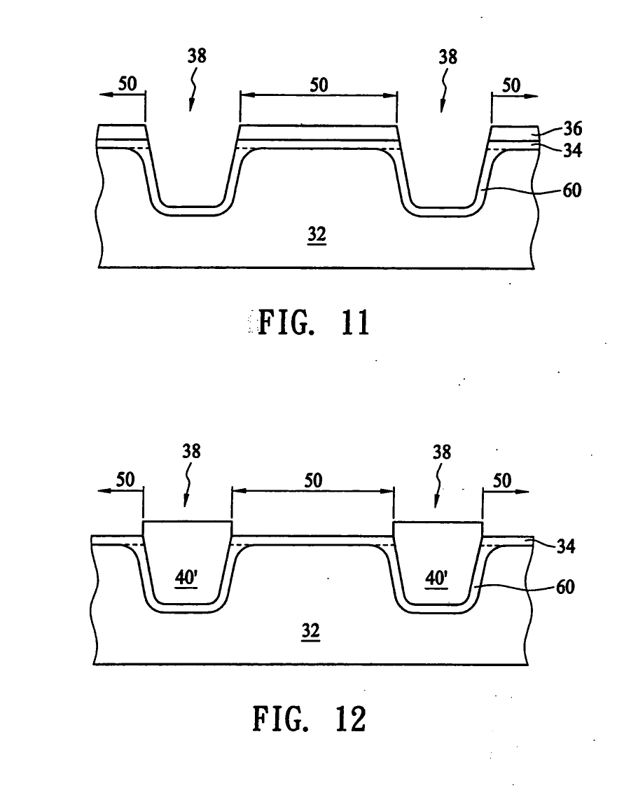

FIG. 11 to FIG. 14 illustrate a method for preparing a gate oxide layer 44″ according to a third embodiment of the present invention. The fabrication processes shown in FIG. 2 are first performed to form the trench 38 in the silicon substrate 32. A thermal oxidation process is then performed to form a liner oxide layer 60 on an inner wall of the trench 38; wherein the oxidation of the silicon substrate 32 changes the profile of the silicon substrate 32 between the trench 38 and the active area 50. Particularly, the thermal oxidation process rounds the profile of the silicon substrate 32 at the edge of the active area 50. Particularly, the silicon substrate 32 has a taper profile at the edge of the active area 50, the liner oxide layer 60 has a round profile at the edge of the active area 50, and the thickness of the liner oxide layer 60 near the border between the active area 50 and the trench 38 is larger than that over the active area 50, as shown in FIG. 11. The liner oxide layer 60 may be made of silicon oxide, silicon nitride or silicon-oxy-nitride.

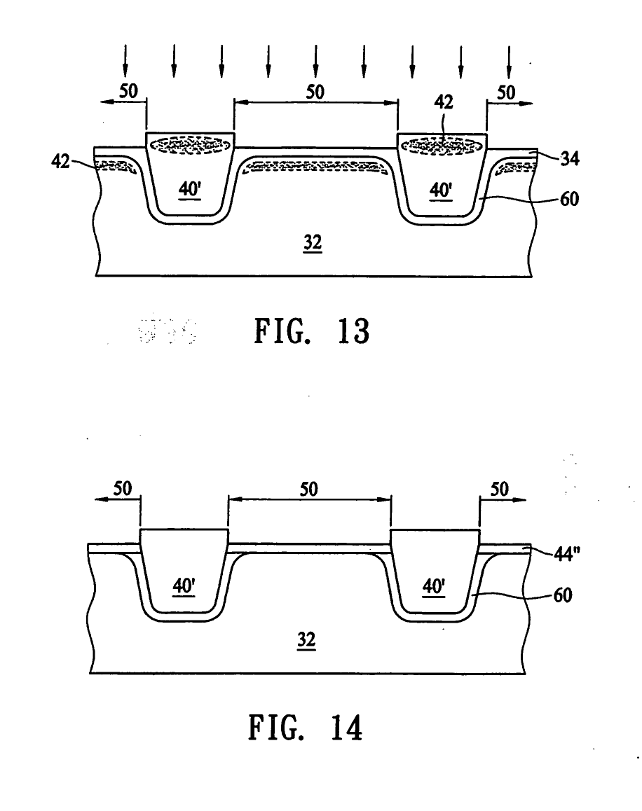

Referring to FIG. 12, the fabrication processes shown in FIG. 3 and FIG. 4 are then performed to form the dielectric block 40′ in the trench 38 (or the fabrication processes shown in FIG. 7 and FIG. 8 are then performed to form the dielectric block 40″ in the trench 38). Subsequently, an implanting process is performed to implant the nitrogen-containing dopants 42 into the dielectric block 40′ and silicon substrate 32 in the active area 50, as shown in FIG. 13. Since the silicon substrate 32 at the edge of the active area 50 is taper and the liner oxide layer 60 has a larger thickness at the edge than at the center of the active area 50, using the liner oxide layer 60 as an implanting mask causes the implanting concentration of the nitrogen-containing dopants 42 at the edge of the active area 50 to be lower than that at the center of the active area 50.

Referring to FIG. 14, a fluoric acid solution is used as an etchant to perform another wet etching process to completely remove the pad oxide layer 34, so as to expose the upper surface of the silicon substrate 32 in the active area 50, and a thermal oxidation process is then performed to form the gate oxide layer 44″ on the upper surface of the silicon substrate 32 in the active area 50. The concentration of the implanted nitrogen-containing dopants 42 at the center is higher than that at the edge of the active area 50, i.e. the number of nitrogen-containing dopants 42 in the shallow interior of the silicon substrate 32 at the edge of the active area is smaller than that at the center of the active area 50. Consequently, the oxidation rate at the center of the active area 50 is slower than that at the edge of the active area 50. Particularly, the inhibiting effects of the nitrogen-containing dopants 42 can compensate for the inconsistent oxidation rate between the edge and the center of the active area 50 due to stress, so as to prevent the gate oxide layer 44′ from being thinner at the edge than at the center of the active area 50.

Compared to the prior art, the embodiment of the present invention implants the nitrogen-containing dopants into the silicon substrate in the active area, and the concentration of the nitrogen-containing dopants at the edge of the active area is lower than that at the center of the active area. Consequently, the oxidation rate of the silicon substrate at the edge of the active area is higher than that at the center of the active area, which can prevent the gate oxide layer from having a smaller thickness at the edge than at the center of the active area due to the inhibiting effects of the nitrogen-containing dopants on the reaction rate of the thermal oxidation process.

In addition, the implanting process implants the nitrogen-containing dopants into the silicon substrate in a self-aligned manner by changing the relative height between the trench and the active area or by changing the profile of the silicon substrate in the active area. That is, there is no need to use a lithographic process to define the implanting region.

The above-described embodiments of the present invention are intended to be illustrative only. Numerous alternative embodiments may be devised by those skilled in the art without departing from the scope of the following claims.

What is claimed is:

1. A method for preparing a gate oxide layer, comprising steps of:
forming a mask layer having at least two openings on a substrate;
forming two trenches in the substrate below the two openings of the mask layer, wherein the two trenches surround an active area;
forming a dielectric block in each of the two trenches, wherein the dielectric block has an upper surface not aligned with an upper surface of the substrate;
implanting nitrogen-containing dopants into the substrate in the active area; and
performing a thermal oxidation process to form a gate oxide layer on the upper surface of the substrate in the active area.

2. The method for preparing a gate oxide layer of claim 1, wherein the step of forming a dielectric block in each of the two trenches comprises:
forming a dielectric layer on the substrate;
performing a planarization process to remove a portion of the dielectric layer above the mask layer to form the dielectric block; and
performing an etching process to remove the mask layer such that the upper surface of the dielectric block is higher than the upper surface of the substrate.

3. The method for preparing a gate oxide layer of claim 1, wherein the step of forming a dielectric block in each of the two trenches comprises:
forming a dielectric layer on the substrate; and
removing a portion of the dielectric layer not covered by the mask layer to form the dielectric block such that the upper surface of the dielectric block is lower than the upper surface of the substrate.

4. The method for preparing a gate oxide layer of claim 1, wherein the nitrogen-containing dopants are ions selected from a group consisting of nitrogen atom, nitrogen gas, nitrous oxide and nitric oxide.

5. The method for preparing a gate oxide layer of claim 1, wherein the nitrogen-containing dopants are implanted into the substrate in the active area in a Gaussian distribution manner.

6. The method for preparing a gate oxide layer of claim 1, wherein concentration of the nitrogen-containing dopants at the center is higher than that at an edge of the active area.

7. A method for preparing a gate oxide layer, comprising steps of:
forming a mask layer having at least two openings on a substrate;
forming two trenches in the substrate below the two openings of the mask layer, wherein the two trenches surround an active area;
forming a taper profile in the substrate between the active area and each of the two trenches;
forming a dielectric block in each of the two trenches;
implanting nitrogen-containing dopants into the substrate in the active area; and
performing a first thermal oxidation process to form a gate oxide layer on an upper surface of the substrate in the active area.

8. The method for preparing a gate oxide layer of claim 7, wherein the step of forming a taper profile in the substrate between the active area and each of the two trenches comprises performing a second thermal oxidation process.

9. The method for preparing a gate oxide layer of claim 8, wherein the second thermal oxidation process rounds the profile of the substrate between the active area and each of the two trenches.

10. The method for preparing a gate oxide layer of claim 8, wherein the second thermal oxidation process forms a liner oxide layer on an inner wall of each of the two trenches, and the liner oxide layer has a round profile at an edge of the active area.

11. The method for preparing a gate oxide layer of claim 7, wherein the step of forming a dielectric block in each of the two trenches comprises:
forming a dielectric layer on the substrate;
performing a planarization process to remove a portion of the dielectric layer above the mask layer to form the dielectric block; and
performing an etching process to remove the mask layer such that the dielectric block has an upper surface higher than the upper surface of the substrate.

12. The method for preparing a gate oxide layer of claim 7, wherein the step of forming a dielectric block in each of the two trenches comprises:
forming a dielectric layer on the substrate; and
removing a portion of the dielectric layer not covered by the mask layer to form the dielectric block such that the dielectric block has an upper surface lower than the upper surface of the substrate.

13. The method for preparing a gate oxide layer of claim 7, wherein the nitrogen-containing dopants are ions selected from a group consisting of nitrogen atom, nitrogen gas, nitrous oxide and nitric oxide.

14. The method for preparing a gate oxide layer of claim 7, wherein the nitrogen-containing dopants are implanted into the substrate in the active area in a Gaussian distribution manner.

15. A method for preparing a gate oxide layer, comprising steps of:
forming two dielectric blocks in two trenches in a substrate, wherein the two dielectric blocks define an active area and each of the two dielectric blocks has an upper surface not aligned with an upper surface of the substrate;
performing an implanting process to implant nitrogen-containing dopants into the substrate in the active area, wherein a concentration of the nitrogen-containing dopants at a center of the active area is higher than that at an edge of the active area; and
performing a thermal oxidation process to form a gate oxide layer on the upper surface of the substrate in the active area, wherein a reaction rate of the thermal oxidation process at the center of the active area is slower than that at the edge of the active area.

16. The method for preparing a gate oxide layer of claim 15, wherein the step of forming two dielectric blocks in two trenches in a substrate comprises:
forming a mask layer having two openings on the substrate;
forming the two trenches in the substrate below the two openings of the mask layer;
forming a dielectric layer on the substrate;
performing a planarization process to remove a portion of the dielectric layer above the mask layer to form the two dielectric blocks; and
removing the mask layer such that upper surfaces of the two dielectric blocks are higher than the upper surface of the substrate.

17. The method for preparing a gate oxide layer of claim 15, wherein the step of forming two dielectric blocks in two trenches in a substrate comprises:
forming a mask layer having two openings on the substrate;
forming the two trenches in the substrate below the two openings of the mask layer;
forming a dielectric layer on the substrate;
removing a portion of the dielectric layer not covered by the mask layer to form the two dielectric blocks such that upper surfaces of the two dielectric blocks are lower than the upper surface of the substrate; and
removing the mask layer.

18. The method for preparing a gate oxide layer of claim 15, wherein the nitrogen-containing dopants are ions selected from a group consisting of nitrogen atom, nitrogen gas, nitrous oxide and nitric oxide.

19. The method for preparing a gate oxide layer of claim 15, wherein the nitrogen-containing dopants are implanted into the substrate in the active area in a Gaussian distribution manner.

20. The method for preparing a gate oxide layer of claim 15, further comprising a step of performing another thermal oxidation process to form a liner oxide layer on an inner wall of each of the two trenches before the step of forming the two dielectric blocks in the two trenches in the substrate, and the liner oxide layer has a round profile at the edge of the active area.
